(19) United States
(12) Patent Application Publication
(10) Pub. No.: US 2006/0105549 A1
(43) Pub. Date: May 18, 2006

(54) Manipulation of micrometer-sized electronic objects with liquid droplets

(76) Inventors: Paulus Cornelis Duineveld, Eindhoven (NL); Menno Willem Jose Prins, Eindhoven (NL); Michel Marcel Jose Decre, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/538,409

(22) PCT Filed: Nov. 17, 2003
(86) PCT No.: PCT/IB03/05273

§ 371 Date: Jun. 10, 2005

(30) Foreign Application Priority Data
Dec. 18, 2002 (EP) 020803912
May 20, 2003 (EP) 031014244

(51) Int. Cl. H01L 21/20; G01N 1/00

(52) U.S. Cl. 438/478; 73/863

(57) ABSTRACT

A system for manipulating a small object (3) comprising a substrate to receive the small object (3), a liquid droplet (4), which carries the small object (3) on the substrate, and a pre-treated surface structure of the substrate in the vicinity (1,2) of the placement position (1) of the small object (3). The small objects (3) like silicon dies in the range from 100 down to 1 micrometer are fine-placed by an evaporating droplet (4). The dies will serve as active electronic elements in large-area displays and other applications.

Manipulation of small objects is in particular of relevance in the fabrication of semiconductor devices. Small electronic components need to be placed accurately on a substrate. Often a crystalline Si wafer is used as substrate. It appears that the cost of semiconductor devices is strongly dependent on the size of the substrate, so that the more semiconductor devices made on the substrate, the lower the production cost per semiconductor device. The number of semiconductor devices accommodated on the substrate, given the size of the surface of the substrate, is increased as smaller sized components are employed. These components need to be manipulated, for example in that they need to be picked-up and placed accurately at predetermined positions on the substrate. The placement of small electronic objects is an important process in the electronics industry. At this moment the positioning of these objects is performed by mechanical placement, so-called pick-and-place. The object size is typically 200 μm and the placement accuracy of the order of 10 μm and this mechanical placement technologies are not suited for dies with a size below 100 μm.

The invention pertains to a system for manipulation of a small object especially electronic objects by using fluid droplets.

A system for manipulation of small objects is known from U.S. Pat. No. 6,294,063. The known system concerns in particular to the manipulation of encapsulated packets. This means that the packets always need to me immersed in other layer of material. The packets could be a solid packet and that solid packet could be a particle of a cell or any material. The known system comprises a reaction surface configured to provide an interaction site for the encapsulated packet. Further an inlet port is provided coupled to the reaction surface to introduce the encapsulated packet onto the reaction surface. A programmable manipulation force is generated to move the packet about the reaction surface by arbitrarily chosen paths. The manipulation force is generated by way of an electric field or by way of a light source. The manipulation force may include a dielectrophoretic force, an electrophoretic force, an optical force or a mechanical force.

A drawback of the known system is that an object must first be immersed to get a packet which can be manipulated but there are shaped solid objects where a front side, left, right up and down can be distinguished, of which not the whole object might be immersible. Further it is often an advantage not to immerse objects. A further drawback of the known system is that the encapsulated packets can only be moved over the reaction surface so that the manipulation and exact positioning becomes more cumbersome as more encapsulated packets are placed on the reaction surface. The control of the orientation and rotation of the objects is out of the scope of electrophoretic manipulation of small objects.

It is the aim of the present invention is to provide a system for the placement and interconnection of small objects like silicon dies in the range of about 1 μm to 100 micrometer on large substrates with high placement accuracy, speed and reliability and at low cost.

This aim is achieved by a system for manipulation of small electronic objects according to the invention comprising a substrate to receive the small object, a liquid droplet that evaporate, which carries the small object on the substrate, and a pre-treated surface structure of the substrate in the vicinity of the placement position of the small object. Due to the presence of a pre-treated surface structure, the object is moved to a well-defined position by the evaporating droplet.

The system according to the invention for manipulating of small objects by using fluid droplets operates on the basis of the physical phenomenon of the surface wetting. The wettability of a liquid is defined as the contact angle between a droplet of the liquid in thermal equilibrium on a horizontal surface. Depending on the type of surface and liquid the droplet may take a variety of shapes. The wetting angle is given by the angle between the interface of the droplet and the horizontal surface. The liquid is seemed wetting between an angle of 90° to 180° and non-wetting between 0° and 90°. A wetting angle of 180° degrees corresponds to perfect wetting and the drop spreads forming a film on the surface.

The present invention in particular focuses on how to control the destination of the fluid droplets with the small objects on the substrate. To this end high wettability spots are introduced and the shape of the high-wettability spots adds to control of orientation of the small objects when the fluid is removed by evaporation.

These and other aspects of the invention are disclosed in the dependent claims and in the following description in which exemplified embodiments of the invention are described with respect to the accompanying drawings. Therein shows:

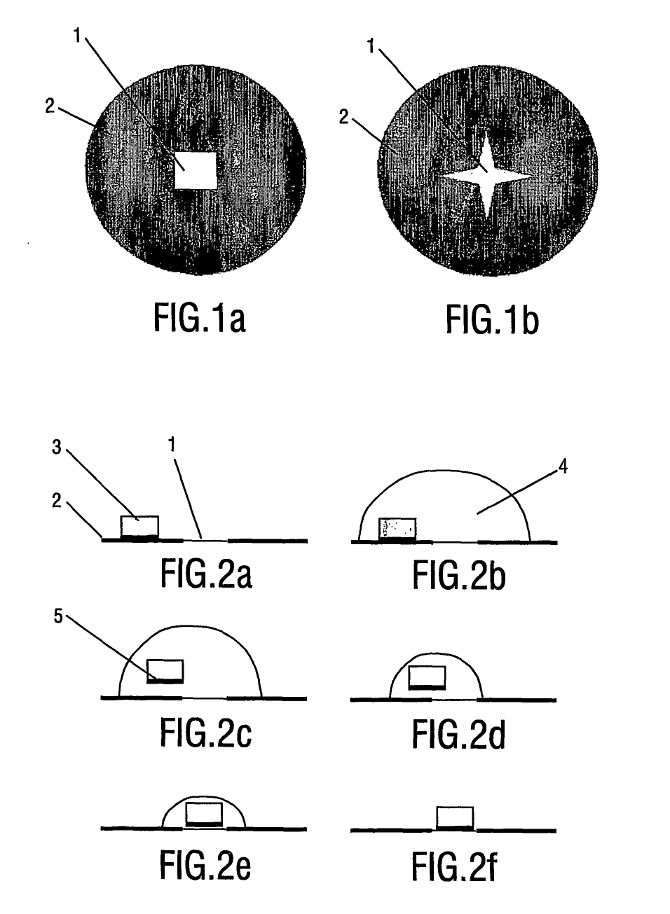

FIG. 1 a possible structure of the surface with difference in wettability around the final placement position of the object;

FIG. 2 the placement of the object due to droplet evaporation;

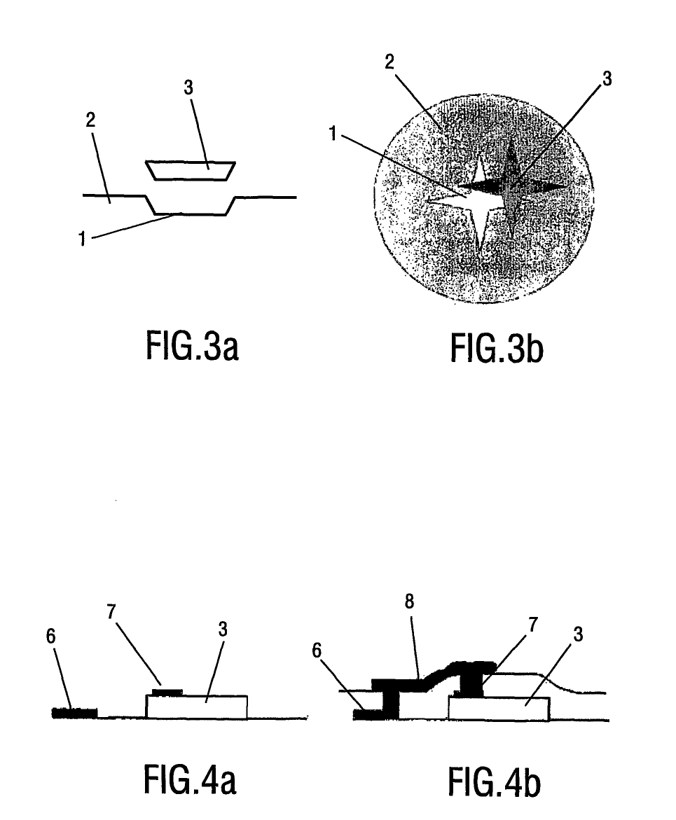

FIG. 3 another method to position the object which is due to a special shape of the object and substrate;

FIG. 4 the interconnection of the small object after placement in standard lithographic way.

One possibility to manipulate small electronic objects like silicon dies by liquid droplets is to make contrast in wettability on the substrate near the placement position of the object. This contrast gives a self-alignment of the object.

FIG. 1a sketches a possible structures of the surface of the substrate wherein the position of the object is the square. An area 2 of the substrate around the final position of the object the surface has been modified, to make it poor-wetting. This part is shown in grey. In the near vicinity 1 of the final placement position of the object, shown as a white square, the wettability of the liquid with the substrate is good. It is especially important that the liquid has a non-zero receding contact angle with the substrate near the placement position of the object—the grey part—, as will be further discussed in the embodiments. Other structures are also possible as shown e.g. in FIG. 1b. The contrast in wettability can be made e.g. with micro-contact printing a monolayer of a suitable molecule. With this technology sub-micron resolution has been shown to be feasible and with wave printing large substrates can be printed with a very good placement accuracy in the order of about 1 micron.

Another possibility is to make physical structures, such as grooves and ridges, to guide the edge of the fluid meniscus to the desired position.

### Embodiment 1

A first embodiment of the invention is to first place the objects with a rough placement method, e.g. laser die transfer, or mechanical placement. With this placement the object is placed somewhere around the final position of the object on the surface 2 which has been modified to poor-wetting.

With an ink-jet printer very small droplets can be formed, with a diameter ranging between 15 and 50 μm. The placement accuracy of the droplets with industrial ink-jet printers is of order 10-15 micron which is sufficient to place the droplet 4 with liquid also on the non-wetting part 2 of the substrate. The next aspect is to dissolve the object 3 in the liquid. This can be done by pre-treatment of the object 3, e.g. to make the side 5 of the object in contact with the substrate hydrophilic, by e.g. a monolayer. When the object 3 is in contact with the liquid, the object 3 will preferably move in the liquid and not adhere to the substrate 2. Another method to achieve that the object 3 becomes part of the droplet 4, is to place a dissolvable layer on the object side 5 which is in contact with the substrate. Due to the contact of the object 3 with the liquid, the layer on the object side 5 dissolved and the object 3 can float freely in the droplet 4. When the object 3 is floating in the liquid droplet 4 the liquid will evaporate. As stated above the properties of the liquid with the substrate are such that the contact line will not pin, but can recede from the non-wetting area. Only at the position where the object 3 has to be placed the liquid has a low contact angle with the substrate and will pin. During evaporation the object 3 remains floating in the droplet 4 and will be moved to the placement position during the evaporation of the solvent. Due to the hydrophilic layer 5 it is energetically more favourable for the object 3 to adhere to the hydrophilic part of the substrate. Finally all solvent evaporates and the object 3 is positioned in place 1. There are no restrictions to a single solvent but there can be used also solvent mixtures to have a favourable Marangoni force, i.e. a force due to a difference in surface tension on the interface of the droplet 4 that can help positioning the object 3 in place. The transportation fluid should be free of dust particles and most probably the process should run in a clean-room environment.

The complete procedure for the fine placement of an object 3 by a printed liquid droplet 4 is sketched in FIG. 2. First the object 3 is placed by rough placement of the object 3 with a different technique on the substrate in the area 2 somewhere around the final position 1 of the object 3 (FIG. 2a). Then a droplet 4 is placed (FIG. 2b) and by dissolving of the object 3 in the droplet 4 it can freely float in the liquid (FIG. 2c). Due to the contrast in surface energy, the evaporating droplet 4 will move to the area with the low contact angle and the object 3 is manipulated to the proper position 1. The sketched thin line represents a good wetting and the thick line a poor wetting area of the substrate (FIG. 2d-2f). The layer 5 on the object 3 is a hydrophilic monolayer. During evaporation the solvent will recede from the area with a high contact angle, but due to the surface energy contrast, it will stick to the low contact angle area.

The orientation of the droplet 4 is important to have a good match with the shape of the placement position. Therefore the object 3 can be directed during the evaporation of the solvent by means of a magnetic field, when the object 3 is provided with a magnetic layer. By means of magnets the object 3 can be rotated in the azimuthal direction, while residing inside the droplet 4. FIG. 3 shows another method to position the object 3. This method for positioning the object 3 is due to a special shape of the object 3 and the final position 1 on the substrate in combination with the liquid movement during evaporation as an example is shown in a side view in FIG. 3a. Another option for rotation of the object 3 in the azimuthal plane is by adapting the shape of the object 3 and wetting region 1 of the substrate like it is shown in FIG. 3b in a top view.

### Embodiment 2

In the first embodiment the object 3 was placed with a “rough” positioning method on the substrate. In a second embodiment the objects 3 are already dissolved in the liquid during ink-jet printing. Objects 3 of very small size of order 5 to 10 micron and smaller can be dissolved in the droplets 4 and placed on the substrate. The procedure for placement of the droplet is similar as in FIG. 2 shown.

The orientation of the object 3 can be done in similar ways as described in the previous embodiment. A flipping of the object is also possible by applying a magnetic field. In the shown figures one object 3 is sketched in the droplet 4. This is an important aspect. There are several ways to have a droplet 4 with a single object 3 landing on the substrate. First this can be done by manipulating the liquid flow inside the ink-jet printer. Another option is to inspect the droplets 4 during flight and let only those droplets 4 pass that contain an object 3. The other droplets are deflected. The deflection of droplets is a standard technique in continuous ink-jet printing. Yet another option is to print the droplets 4 and inspect the substrate after printing. A new droplet 4 is printed where objects are missing. With multi-nozzle printers one can print easily about 100 droplets per second. By optical inspection it may also be possible to remove droplets 4 with more than one object 3. Alternatively, droplets with more than one object can be spotted on the substrate, and non-sticking objects are later removed.

An important issue in the placement of objects 3 on a substrate is the interconnect of the object 3 to the outside world. There are several options for this which are standard. First it can be done in the standard lithographic way. This is sketched in FIG. 4. In FIG. 4a the object is shown after placement of the object 3 close to a connecting line 6. On top of the object 3 there is a conducting part 7. By standard lithography via's 8 are made and the object 3 is connected.

As sketched in FIG. 1 a monolayer is made by micro-contact printing. This monolayer can be removed after deposition of the small object and before interconnect with e.g. UV-ozone or plasma treatment. In this way the interconnect will not be hindered by the monolayer.

Another option for interconnect is by heating the object on the substrate and melting a layer of low melting temperature metal on both object and substrate to form a connection.

The described systems allow manipulation of small objects in the range of about 1 μm to 100 μm on large substrates with high placement accuracy, speed and reliability at low cost. There are several applications that can benefit from this assembly system. This assembly is called ‘Meso-assembly’, which is the placement and interconnect of dies in the above mentioned range on large substrates. The most prominent application is active-matrix displays. For example, PolyLED-TV and Active-Matrix-PolyLED-Mobile, require electronic switches with high electronic mobilities and high reliability. ‘Meso-assembly’ is potentially an alternative to low-temperature poly-silicon. Besides active-matrix displays, also other applications can benefit from ‘meso-assembly’ technologies like large-area X-ray detectors with direct conversion, chip-cards and tags, LED chips on silicon submounts and others.

1. A system for manipulation of a small object comprising
a substrate to receive the small object (3), a liquid droplet (4) that evaporate, which droplet (4) carries the small object (3) on the substrate,
a pre-treated surface structure of the substrate in the vicinity (1,2) of the placement position of the small object (3), wherein the small object is moved to a well-defined placement position (1) by the evaporation of the droplet (4).

2. A system for manipulation of a small object as claimed in claim 1, wherein the surface structure of the substrate is pre-treated chemically in that way, that the final placement position (1) of the object is modified to make it good-wetting and that the near vicinity (2) of the placement position of the small object (3) is poor-wetting to make contrast in wettability on the substrate near the placement position (1,2) of the small object (3).

3. A system for manipulation of a small object as claimed in claim 2, wherein the contrast in wettability of substrate is provided by a monolayer of a suitable molecule, which monolayer is made by micro-contact printing.

4. A system for manipulation of a small object as claimed in claim 1, wherein the small (3) object is pre-treated by a monolayer to make the side (5) of the object (3) in contact with the substrate hydrophilic.

5. A system for manipulation of a small object as claimed in claim 1, wherein the small object (3) is pre-treated by a dissolvable layer.

6. A system for manipulation of a small object as claimed in claim 1, wherein the surface structure of the substrate is pre-treated physically, in that way that the edge of the fluid meniscus is guided by grooves and ridges of the physically pre-treated structure to the final placement position of the small object.

7. A system for manipulation of a small object as claimed in claim 1, wherein the object (3) is aligned to match to the placement position (1) by means of a magnetic field.

8. A system for manipulation of a small object as claimed in claim 1, wherein the placement position (1) on the substrate has a shape which corresponds to the shape of the small object (3), so that the object (3) is aligned to match with the final placement position (1) during evaporation of the droplet (4).

9. A method of manipulation of a small object having a
a substrate with a pre-treated surface structure to receive the small object (3), which object (3) is pre-treated by a monolayer to make the side (5) of the object (3) in contact with the substrate hydrophilic,
placing the small object by rough placement of the object on the substrate somewhere around the final position (1) of the object (3),
placing a droplet (4) on the substrate in the vicinity of the final position (1) of the small object,
dissolving of the object (3) in the droplet (4) that the object can freely float in the liquid,
moving the droplet (4) from the poor wetting area to the good wetting area and
positioning the object (3) to the proper position (1) by the evaporation of the droplet,
interconnecting the object (3) by standard lithographic way.
